(19) United States
(12) Patent Application Publication
(10) Pub. No.: US 2026/0023227 A1
(43) Pub. Date: Jan. 22, 2026

(54) SEMICONDUCTOR PACKAGE AND DATA TRANSMISSION METHOD FOR SEMICONDUCTOR PACKAGE

(71) Applicant: Shanghai Xizhi Technology Co., Ltd., Shanghai (CN)

(72) Inventors: Huaiyu MENG, Shanghai (CN); Yichen SHEN, Shenzhen, Guangdong (CN)

(73) Assignee: Shanghai Xizhi Technology Co., Ltd., Shanghai (CN)

(21) Appl. No.: 18/993,552

(22) PCT Filed: Jun. 22, 2023
(86) PCT No.: PCT/CN2023/101987

§ 371 Date: Jan. 12, 2025

(30) Foreign Application Priority Data
Jul. 11, 2022 (CN) 202210808454.6

(51) Int. Cl. G02B 6/42; H01L 23/00; H01L 25/18; H10B 80/00

(52) U.S. Cl. CPC G02B 6/4274; G02B 6/4204; H01L 24/16; H01L 25/18; H01L 2224/16145; H01L 2224/16227; H10B 80/00

(57) ABSTRACT

A semiconductor package (100) and a data transmission method for the semiconductor package (100) are disclosed. The semiconductor package (100) includes a photonic integrated circuit chip (110), a plurality of memory chips (120), and a first chip (130). The first chip (130) is electrically connected to the photonic integrated circuit chip (110), so that data is transmitted between the first chip (130) and the photonic integrated circuit (110) through an electrical signal. The first chip (130) is further electrically connected to each memory chip (120), so that data is transmitted between the first chip (130) and each of the plurality of memory chips (120) via electrical signals.

This application claims priority to Chinese Patent Application No. 202210808454.6 filed with CNIPA on Jul. 11, 2022, and entitled “SEMICONDUCTOR PACKAGE AND DATA TRANSMISSION METHOD FOR SEMICONDUCTOR PACKAGE”. The disclosure of the aforementioned application is incorporated herein by reference in its entirety.

### TECHNICAL FIELD

The present application relates to the field of semiconductors, and more specifically, to a semiconductor package and a data transmission method for the semiconductor package.

### BACKGROUND

Memory, as an important component in electronic devices or electronic systems, usually relies on electrical connection wires to input/output electrical signals to transmit data. With the growing computing requirements, the electrical connection wires have restricted high-speed data transmission and lead to increased power consumption.

### TECHNICAL SOLUTIONS

Embodiments of the present application provide a semiconductor package and a data transmission method for the semiconductor package.

In an aspect of the present disclosure, some embodiments of the present disclosure provide a semiconductor package including: a photonic integrated circuit chip; a plurality of memory chips; and a first chip. The first chip is electrically connected to the photonic integrated circuit chip, so that data is transmitted between the first chip and the photonic integrated circuit through an electrical signal, and the first chip is further electrically connected to each of the plurality of memory chips, so that data is transmitted between the first chip and each of the plurality of memory chips through electrical signals.

In some embodiments, the first chip is configured to convert a plurality of first electrical signals from the plurality of memory chips into a second electrical signal to be transmitted to the photonic integrated circuit chip, and a data transmission rate of the second electrical signal is greater than a data transmission rate of each of the plurality of first electrical signals.

In some embodiments, the first chip includes a parallel-to-serial conversion unit configured to perform a parallel-to-serial conversion on data represented by the plurality of first electrical signals from the plurality of memory chips to generate the second electrical signal.

In some embodiments, the photonic integrated circuit chip is configured to convert the second electrical signal into a second optical signal.

In some embodiments, the photonic integrated circuit chip is configured to output the second optical signal.

In some embodiments, the photonic integrated circuit chip is configured to convert a first optical signal into a third electrical signal, and the first chip is configured to convert the third electrical signal into a plurality of fourth electrical signals to be transmitted to the plurality of memory chips. A data transmission rate of the third electrical signal is greater than a data transmission rate of each of the plurality of fourth electrical signals.

In some embodiments, the first chip includes a serial-to-parallel conversion unit configured to perform a serial-to-parallel conversion on data represented by the third electrical signal from the photonic integrated circuit chip to generate the plurality of fourth electrical signals.

In some embodiments, the plurality of memory chips are disposed around the photonic integrated circuit chip.

In some embodiments, the semiconductor package includes a substrate. The photonic integrated circuit chip, the plurality of memory chips, and the first chip are disposed on a same side of the substrate, and the photonic integrated circuit chip is disposed between the first chip and the substrate.

In some embodiments, the substrate includes a first conductive wiring structure, and the photonic integrated circuit chip includes a second conductive wiring structure. An electrical connection path from at least one of the plurality of memory chips to the first chip includes a conductive path that passes through the first conductive wiring structure and the second conductive wiring structure in sequence, so as to transmit at least one of the plurality of first electrical signals.

In some embodiments, the photonic integrated circuit chip includes a first surface and a second surface, the first surface and the second surface respectively face the first chip and the substrate, and the second conductive wiring structure extends between the first surface and the second surface of the photonic integrated circuit chip.

In another aspect, some embodiments of the present disclosure further provide a data transmission method for a semiconductor package. The semiconductor package includes a photonic integrated circuit chip, a plurality of memory chips, and a first chip. The method includes: receiving, by the first chip, a plurality of first electrical signals from the plurality of memory chips;
converting, by the first chip, the plurality of first electrical signals into a single second electrical signal, wherein a data transmission rate of the second electrical signal is greater than a data transmission rate of each of the plurality of first electrical signals; receiving, by the photonic integrated circuit chip, the second electrical signal; and converting, by the photonic integrated circuit chip, the second electrical signal into a second optical signal.

In some embodiments, the first chip performs a parallel-to-serial conversion on data represented by the plurality of first electrical signals from the plurality of memory chips to generate the second electrical signal.

In some embodiments, the photonic integrated circuit chip outputs the second optical signal.

Through the embodiments of the present disclosure, electrical signals with lower data transmission rates, which are input into or output from the memories may be processed and matched with higher optical signal transmission rates, and further, data may be transmitted or output through optical signals. In addition, an overall electrical connection and package size of the semiconductor package are optimized.

Various aspects, features, advantages, etc., of the embodiments of the present disclosure will be described in detail below with reference to the accompanying drawings. The above aspects, features, advantages, etc., of the present disclosure will become clearer from the following detailed description in conjunction with the accompanying drawings.

Refer to the following description and to the accompanying drawings, specific embodiments of the present disclosure are disclosed in detail and the manner in which the principles of the present disclosure may be employed is illustrated. It should be understood that embodiments of the present disclosure are not thereby limited in scope. Embodiments of the present disclosure include numerous changes, modifications, and equivalents, within the spirit and scope of the appended claims.

Features described and/or illustrated with respect to one embodiment may be used in the same or similar manner in one or more other embodiments, combined with features in the other embodiments, or in place of features in the other embodiments.

It should be emphasized that the term “comprising” when used herein refers to the presence of features, integers, steps, or components, but does not exclude the presence or addition of one or more other features, integers, steps, or components.

### BRIEF DESCRIPTION OF THE DRAWINGS

In order to more clearly illustrate the technical solutions in the embodiments of the present disclosure, the drawings needed to be used in the description of the embodiments will be briefly introduced below. Apparently, the drawings in the following description are only some embodiments of the present disclosure. For those skilled in the art, other drawings can also be obtained based on these drawings without exerting creative efforts.

FIG. 1 shows a top view of a semiconductor package according to some exemplary embodiments of the present disclosure.

FIG. 2 shows a side view of the semiconductor package according to some exemplary embodiments of the present disclosure.

FIG. 3 shows a schematic diagram of an exemplary photonic integrated circuit chip of the present disclosure.

### EMBODIMENTS OF THE INVENTION

In order to facilitate understanding of various aspects, features and advantages of the technical solution of the present disclosure, the present disclosure is described in detail below with reference to the accompanying drawings. It should be understood that the various embodiments described below are only for illustration and are not intended to limit the scope of the present disclosure.

The terminology used in the present disclosure is for the purpose of describing particular embodiments only and is not intended to limit the disclosure. As used herein, singular forms “a,” “an,” and “the” are intended to include the plural forms as well, unless the context clearly indicates otherwise. It will be further understood that the terms “comprising” and/or “including” when used in the description specify the presence of stated features, integers, steps, operations, elements and/or parts, but do not exclude the presence or addition of one or more other features, integers, steps, operations, elements, components and/or groups thereof. As used herein, the term “and/or” includes any and all combinations of one or more of associated items having been listed, and the phrase “at least one of A and B” refers to only A, only B, or both A and B. In the present disclosure, the chip may include a die. In the present disclosure, features of one embodiment may also be applied to and appropriately incorporated as the features of other embodiments described in this disclosure.

Memory, as an important component in electronic devices or electronic systems, usually relies on electrical connection wires to input/output electrical signals to transmit data. With the growing computing requirements, the electrical connection wires have restricted high-speed data transmission, and a large number of electrical connection wires may further lead to increased power consumption.

The inventors have realized that under certain circumstances, data transmission may be carried out through optical signals to replace some electrical interconnections. However, electrical signal data output by a single memory chip usually has a low transmission rate and cannot match a large data bandwidth of optical interconnections. In addition, in scenarios where data transmission is required between multiple memory chips, suitable packaging structures are required.

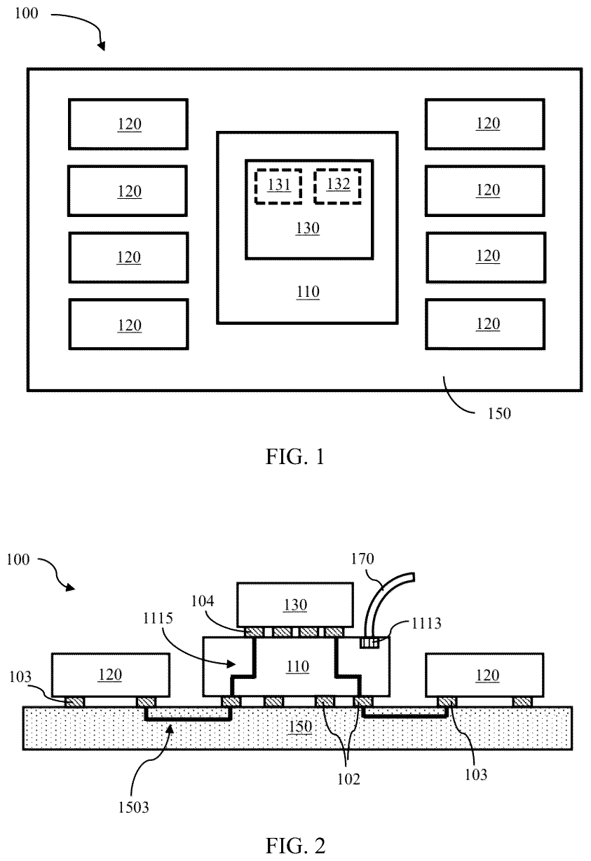

FIG. 1 shows a top view of a semiconductor package according to some exemplary embodiments of the present disclosure, which shows that the semiconductor package includes: a photonic integrated circuit chip 110, a plurality of memory chips 120, and a first chip 130. The first chip 130 is electrically connected to the photonic integrated circuit chip 110, so that data is transmitted between the first chip 130 and the photonic integrated circuit chip 110 through electrical signals. The first chip 130 is further electrically connected to each of the plurality of memory chips 120, so that data is transmitted between the first chip 130 and each memory chip 120 through electrical signals.

FIG. 1 further shows a substrate 150, which may include a printed circuit board, an interposer, or other suitable semiconductor packaging substrate. For example, the plurality of memory chips 120 or some of the plurality of memory chips 120 are disposed around the photonic integrated circuit chip 110.

The semiconductor package 100 may convert low-speed data transmitted by the plurality of memory chips 120 for high-speed optical data transmission. In addition, a layout and connection of the memory chips 120 and the photonic integrated circuit chip 110 of the semiconductor package 100 in FIG. 1 are configured to optimize an overall electrical connection and a package size of the semiconductor package 100. The electrical signal transmission between the first chip 130 and each memory chip 120 may include at least one of the following: the first chip 130 sending data to the memory chip 120 and the first chip 130 receiving data from the memory chip 120. Further, the plurality of memory chips 120 may perform data transmission with the photonic integrated circuit chip 110 through the first chip 130. Other functions of the first chip 130 will be described later.

FIG. 2 shows a side view of the semiconductor package 100. The semiconductor package 100 includes an optical fiber 170 that may be used to input light to or output light from the photonic integrated circuit chip 110. The photonic integrated circuit chip 110 may include an optical coupling structure 1113. The optical coupling structure 1113 may be used to be optically coupled with the optical fiber 170, and may further be coupled to a waveguide in the photonic integrated circuit chip 110. The number of the coupling structure 1113 and the number of the optical fiber 170 may be one or more. For example, eight optical coupling structures 1113 are respectively connected to eight optical fibers 170, of which four optical fibers 170 are used to input optical signals and four optical fibers are used to output optical signals. The optical fiber 170 may be replaced by, for example, a photonic lead or other off-chip waveguide, for inputting light into the photonic integrated circuit chip 110 or outputting light from the photonic integrated circuit chip 110.

In FIG. 2, the photonic integrated circuit chip 110 and the memory chip 120 are disposed on the substrate 150, and the first chip 130 is disposed on the photonic integrated circuit chip 110. Therefore, the first chip 130 is indirectly disposed on the substrate 150. The semiconductor package 100 includes a first bonding layer 102, a second bonding layer 103, and a third bonding layer 104. The first bonding layer 102 is used to electrically connect the photonic integrated circuit chip 110 to the substrate. The second bonding layer 103 is used to electrically connect each memory chip 120 to the substrate. The third bonding layer 104 may electrically connect the first chip 130 to the photonic integrated circuit chip 110. For example, the plurality of memory chips 120 are arranged around the photonic integrated circuit chip 110, to allow an appropriate spacing therebetween when the memory chips 120 are connected to a first conductive wiring structure of the photonic integrated circuit chip 110. In some embodiments, the electrical connections may be realized through wire bonding as a substitute for the bonding layers.

For example, when each memory chip 120 is electrically connected to the first chip 130, an electrical connection path from the memory chip 120 to the first chip 130 includes a conductive path passing through the first conductive wiring structure 1503 of the substrate 150 and a second conductive wiring structure 1115 of the photonic integrated circuit chip 110. The conductive path allows electrical signals to be transmitted between the memory chips 120 and the first chip 130 for data transmission. Thereby, wiring resistance of the electrical connection may be reduced. For example, the second conductive wiring structure 1115 of the photonic integrated circuit chip 110 extends a first surface and a second surface of the photonic integrated circuit chip. The first surface and the second surface respectively face the first chip 130 and the substrate 150. Since the second conductive wiring structure 1115 provided in the photonic integrated circuit chip 110 provides a conductive connection channel, multiple conductive channels may be arranged between the memory chip 120 and the first chips 130 to transmit multiple electrical signals.

The second conductive wiring structure 1115 of the photonic integrated circuit chip 110 may include a conductive hole that may pass through one or more semiconductor layers of the photonic integrated circuit chip 110. The second conductive wiring structure 1115 may further include suitable conductive layers such as a pad, etc.

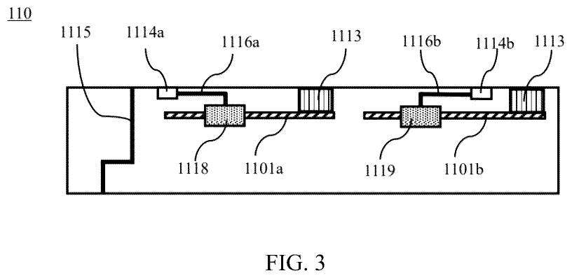

FIG. 3 shows a side view of the photonic integrated circuit chip 110 according to some embodiments. The photonic integrated circuit chip 110 may include waveguides 1101a/1101b, an electro-optical conversion unit 1118, and a photoelectric conversion unit 1119. The electro-optical conversion unit 1118 is coupled to the waveguide 1101a, and the photoelectric conversion unit 1119 is coupled to the waveguide 1101b. The electro-optical conversion unit 1118 may include a modulator to modulate at least one of the characteristics such as phase, intensity, and the like of light based on an electrical signal. Each of the electro-optical conversion unit 1118 and the photoelectric conversion unit 1119 may be electrically connected to its corresponding conductive port through a conductive structure for receiving or sending electrical signals. The electro-optical conversion unit 1118 is electrically connected to a conductive port 1114a through a conductive structure 1116a to receive an electrical signal for modulation, and the electrical signal may come from the first chip (not shown in FIG. 3). The photoelectric conversion unit 1119 may convert an optical signal into an electrical signal. The photoelectric conversion unit 1119 may be electrically connected to the conductive port 1114b through a conductive structure 1116b to transmit the electrical signal.

The photonic integrated circuit chip 110 may be electrically connected to the first chip 130 through a bonding layer (such as the third bonding layer 104 in FIG. 2), and the bonding layer may be connected to the second conductive wiring structure 1115, the conductive ports 1114a/1114b, and the conductive structures 1116a/1116b.

### First Chip

The first chip 130 may be electrically connected to the plurality of memory chips 120 through electrical signal transmission wiring for communication, such as data transmission, with each memory chip 120. In this way, the first chip 130 may receive data from the plurality of memory chips 120, and send data to the plurality of memory chips 120. The data transmission of the memory chip 120 via electrical signal communication usually has a low rate, and thus the lower rate data from the plurality of memory chips 120 may be converted in the first chip 130. For example, through a parallel-to-serial conversion by a parallel-to-serial conversion unit 131 (see FIG. 1) in the first chip 130, parallel data from the plurality of memory chips 120 is converted into serial data with a higher transmission rate, and the serial data is transmitted as an electrical signal to the photonic integrated circuit chip 110 and undergoes an electro-optical conversion in the photonic integrated circuit chip 110 to be converted into an optical signal for further transmission. The electro-optical conversion may be realized through an electro-optical conversion unit (for example, a modulator) in the photonic integrated circuit chip 110.

The first chip 130 may further be used to receive an electrical signal from the photonic integrated circuit chip 110. The data represented by the electrical signal is converted into multi-channel electrical signals through a serial-to-parallel conversion unit 132 (see FIG. 1) in the first chip 130, and the multi-channel electrical signals are respectively transmitted to the plurality of memory chips 120 to realize data transmission. In some exemplary embodiments, data transmitted by an optical signal in the photonic integrated circuit is converted into an electrical signal by the photoelectric conversion unit 1119, and the electrical signal is transmitted to the first chip 130. The first chip 130 converts the serial data represented by the electrical signal from the photonic integrated circuit chip 110 into multi-channel parallel data and transmit the multi-channel parallel data respectively to the plurality of memory chips 120.

### Photonic Integrated Circuit Chip

The photonic integrated circuit chip 110 may include photonic devices such as an optical coupling structure, a waveguide, a photoelectric conversion unit, an electro-optical conversion unit, a light source. The number of the various photonic devices may be configured as needed, which may be one or more. For example, the electro-optical conversion unit may include a modulator to convert an electrical signal into an optical signal. For example, the optical coupling structure may be used to optically couple with a laser or an optical fiber, thereby inputting an optical signal to the photonic integrated circuit chip 110 or outputting an optical signal from the photonic integrated circuit chip 110, for example, by using an optical fiber for the input and output of optical signals. The optical coupling structure may include grating couplers, end face couplers, etc. For example, the waveguide may be used to transmit optical signals and serve as a channel for information propagation. For example, the photoelectric conversion unit may include a photodetector for converting an optical signal into an electrical signal, and the photodetector may include, for example, a photodiode. For example, the photonic integrated circuit chip 110 includes a light source, and the light generated by the light source may be coupled to the waveguide and may further be modulated by an electrical signal.

For example, an initial optical signal that does not carry information may be input into the waveguide of the photonic integrated circuit chip 110 through a first optical coupling structure, and then modulated by the electrical signal to generate an optical signal carrying information which may be output from a second optical coupling structure, for example, to an optical fiber.

### Memory Chip

The memory chips 120 may each be a read-only memory (ROM), a random access memory (RAM), a dynamic random access memory (DRAM), etc. The memories may be arranged in different manners and/or the number (e.g., 4, 6, 12, etc.) of the memories may vary, depending on the needs.

In some embodiments, the first chip 130 is configured to convert a plurality of first electrical signals from the plurality of memory chips 120 into a single second electrical signal to be transmitted to the photonic integrated circuit chip 110, and a data transmission rate of the second electrical signal is greater than a data transmission rate of each of the plurality of first electrical signals.

In some embodiments, the first chip 130 includes a parallel-to-serial conversion unit 131 configured to perform a parallel-to-serial conversion on data represented by the plurality of first electrical signals from the plurality of memory chips 120 to generate the second electrical signal.

In some embodiments, the photonic integrated circuit chip 110 is configured to convert the second electrical signal into a second optical signal.

In some embodiments, the photonic integrated circuit chip 110 is further configured to output the second optical signal, for example, via an optical coupling port.

In some embodiments, the photonic integrated circuit chip 110 is configured to convert a first optical signal into a third electrical signal. The first chip 130 is configured to convert a single third electrical signal from the photonic integrated circuit chip 110 into a plurality of fourth electrical signals to be transmitted to the plurality of memory chips 120. A data transmission rate of the third electrical signal is greater than a data transmission rate of each of the plurality of fourth electrical signals.

In some embodiments, the first chip 130 includes the serial-to-parallel conversion unit 132 configured to perform a serial-to-parallel conversion on data represented by the single third electrical signal from the photonic integrated circuit chip 110 to generate the plurality of fourth electrical signals.

In some embodiments, the plurality of memory chips 120 are disposed around the photonic integrated circuit chip 110.

In some embodiments, the semiconductor package 100 includes the substrate 150. The photonic integrated circuit chip 110, the plurality of memory chips 120, and the first chip 130 are disposed on a same side of the substrate 150, and the photonic integrated circuit chip 110 is disposed between the first chip 130 and the substrate 150.

In some embodiments, the semiconductor package 100 includes the substrate 150. The substrate 150 includes the first conductive wiring structure 1503, and the photonic integrated circuit chip 110 includes the second conductive wiring structure 1115. An electrical connection path from at least one of the memory chips 120 to the first chip 130 includes a conductive path that passes through the first conductive wiring structure 1503 and the second conductive wiring structure 1115 in sequence, so as to transmit at least one of the plurality of first electrical signals.

In some embodiments, the photonic integrated circuit chip 110 includes a first surface and a second surface. The first surface and the second surface respectively face the first chip 130 and the substrate 150. The second conductive wiring structure 1115 extends between the first surface and the second surface of the photonic integrated circuit chip 110.

An exemplary embodiment of the present disclosure provides a data transmission method for a semiconductor package. The semiconductor package includes: a photonic integrated circuit chip 110, a plurality of memory chips 120, and a first chip 130. The method includes: receiving, by the first chip 130, a plurality of first electrical signals from the plurality of memory chips 120; converting, by the first chip 130, the plurality of first electrical signals into a second electrical signal, wherein a data transmission rate of the second electrical signal is greater than a data transmission rate of each of the plurality of first electrical signals; receiving, by the photonic integrated circuit chip 110, the second electrical signal; and converting, by the photonic integrated circuit chip 110, the second electrical signal into a second optical signal.

In some embodiments, the photonic integrated circuit chip 110 outputs the second optical signal.

In some embodiments, the first chip 130 generates the second electrical signal by performing a parallel-to-serial conversion on data represented by the plurality of first electrical signals from the plurality of memory chips.

In some embodiments, the photonic integrated circuit chip 110 outputs the second optical signal.

In addition, in describing the semiconductor package 100 provided by the related embodiments of the present disclosure, the transmission of the electrical signals and of the optical signals and other related features have been described, which are also applicable to the data transmission method for the semiconductor package and will not be repeated herein.

Those skilled in the art should understand that the above disclosure is merely some implementation modes of the present disclosure, and cannot be used to limit the protection scope of claimed by the present disclosure. Equivalent changes made according to the implementation modes of the present disclosure will fall into the scope defined by claims of the present disclosure.

1. A semiconductor package, comprising:
a photonic integrated circuit chip;
a plurality of memory chips; and
a first chip, wherein the first chip is electrically connected to the photonic integrated circuit chip, so that data is transmitted between the first chip and the photonic integrated circuit through an electrical signal, and
the first chip is further electrically connected to each of the plurality of memory chips, so that data is transmitted between the first chip and each of the plurality of memory chips through electrical signals.

2. The semiconductor package of claim 1, wherein the first chip is configured to convert a plurality of first electrical signals from the plurality of memory chips into a second electrical signal to be transmitted to the photonic integrated circuit chip, and a data transmission rate of the second electrical signal is greater than a data transmission rate of each of the plurality of first electrical signals.

3. The semiconductor package of claim 2, wherein the first chip comprises a parallel-to-serial conversion unit configured to perform a parallel-to-serial conversion on data represented by the plurality of first electrical signals from the plurality of memory chips to generate the second electrical signal.

4. The semiconductor package of claim 3, wherein the photonic integrated circuit chip is configured to convert the second electrical signal into a second optical signal.

5. The semiconductor package of claim 4, wherein the photonic integrated circuit chip is configured to output the second optical signal.

6. The semiconductor package of claim 3, wherein the photonic integrated circuit chip is configured to convert a first optical signal into a third electrical signal, the first chip is configured to convert the third electrical signal into a plurality of fourth electrical signals to be transmitted to the plurality of memory chips, wherein a data transmission rate of the third electrical signal is greater than a data transmission rate of each of the plurality of fourth electrical signals.

7. The semiconductor package of claim 6, wherein the first chip comprises a serial-to-parallel conversion unit configured to perform a serial-to-parallel conversion on data represented by the third electrical signal from the photonic integrated circuit chip to generate the plurality of fourth electrical signals.

8. The semiconductor package of claim 3, wherein the plurality of memory chips are disposed around the photonic integrated circuit chip.

9. The semiconductor package of claim 3, comprising a substrate, wherein the photonic integrated circuit chip, the plurality of memory chips, and the first chip are disposed on a same side of the substrate, and the photonic integrated circuit chip is disposed between the first chip and the substrate.

10. The semiconductor package of claim 9, wherein the substrate comprises a first conductive wiring structure, the photonic integrated circuit chip comprises a second conductive wiring structure, and
wherein an electrical connection path from at least one of the plurality of memory chips to the first chip comprises a conductive path that passes through the first conductive wiring structure and the second conductive wiring structure in sequence, so as to transmit at least one of the plurality of first electrical signals.

11. The semiconductor package of claim 10, wherein the photonic integrated circuit chip comprises a first surface and a second surface, the first surface and the second surface respectively face the first chip and the substrate, and the second conductive wiring structure extends between the first surface and the second surface of the photonic integrated circuit chip.

12. A data transmission method for a semiconductor package, wherein the semiconductor package comprises a photonic integrated circuit chip, a plurality of memory chips, and a first chip, and the method comprises:
receiving, by the first chip, a plurality of first electrical signals from the plurality of memory chips;
converting, by the first chip, the plurality of first electrical signals into a single second electrical signal, wherein a data transmission rate of the second electrical signal is greater than a data transmission rate of each of the plurality of first electrical signals;
receiving, by the photonic integrated circuit chip, the second electrical signal; and
converting, by the photonic integrated circuit chip, the second electrical signal into a second optical signal.

13. The data transmission method of claim 12, further comprising: performing, by the first chip, a parallel-to-serial conversion on data represented by the plurality of first electrical signals from the plurality of memory chips to generate the second electrical signal.

14. The data transmission method of claim 12, further comprising outputting the second optical signal by the photonic integrated circuit chip.

15. The data transmission method of claim 13, further comprising:
converting, by the photonic integrated circuit chip, a first optical signal into one or more third electrical signals,
converting, by the first chip, a single one of the one or more third electrical signals into a plurality of fourth electrical signals to be transmitted to the plurality of memory chips,
wherein a data transmission rate of the single third electrical signal is greater than a data transmission rate of each of the plurality of fourth electrical signals.

16. The data transmission method of claim 15, wherein the converting of the first optical signal into the one or more third electrical signals comprises:
performing, by a serial-to-parallel conversion unit of the photonic integrated circuit chip, a serial-to-parallel conversion on data represented by the single third electrical signal from the photonic integrated circuit chip to generate the plurality of fourth electrical signals.
